(19) United States
(12) Patent Application Publication
(10) Pub. No.: US 2025/0336637 A1
(43) Pub. Date: Oct. 30, 2025

(54) WIRELESS CHAMBER INTERIOR SENSOR

(71) Applicant: Applied Materials, Inc., Santa Clara, CA (US)

(72) Inventors: QIANYI XIE, Sunnyvale, CA (US); CHUANG-CHIA LIN, San Ramon, CA (US)

(21) Appl. No.: 18/648,144

(22) Filed: Apr. 26, 2024

(51) Int. Cl. H01J 37/244; H01J 37/32; H02J 50/20

(52) U.S. Cl. CPC H01J 37/244; H01J 37/3211; H01J 2237/24564; H01J 2237/24578; H01J 2237/24585; H02J 50/20

(57) ABSTRACT

Embodiments disclosed herein relate to an apparatus that includes a chamber with an interior surface, and a sensor system coupled to the interior surface. In an embodiment, the sensor system includes a board, and a sensor antenna on the board. In an embodiment, a sensor is communicatively coupled to the sensor antenna, where the sensor is configured to be powered by the sensor antenna. In an embodiment, a chamber antenna is within the chamber, where the chamber antenna is configured to communicatively couple with the sensor antenna.

### BACKGROUND

### 1) Field

Embodiments of the present disclosure pertain to the field of wireless chamber interior sensors.

### 2) Description of Related Art

Processing chambers, such as a vacuum chambers, are used extensively in semiconductor manufacturing process flows. Vacuum chambers may be suitable for supporting plasmas in order to process substrates within the chamber. For example, semiconductor wafers (e.g., silicon wafers) can be processed in a plasma environment. The plasma may be used in order to deposit layers on the substrate, etch portions of the substrate, treat surfaces of the substrate, and/or the like.

In order to maintain high process uniformity and/or control of processing conditions, it is beneficial to closely monitor the chamber environment. For example, the deposition of material on interior surfaces of the chamber may negatively impact process uniformity or yield. For example, particles from layers deposited on chamber sidewalls can flake off and deposit on the substrate. This can result in yield decreases in some instances. Accordingly, process monitoring sensors have been deployed within the chamber to monitor chamber conditions.

### SUMMARY

Embodiments disclosed herein relate to an apparatus that includes a chamber with an interior surface, and a sensor system coupled to the interior surface. In an embodiment, the sensor system includes a board, and a sensor antenna on the board. In an embodiment, a sensor is communicatively coupled to the sensor antenna, where the sensor is configured to be powered by the sensor antenna. In an embodiment, a chamber antenna is within the chamber, where the chamber antenna is configured to communicatively couple with the sensor antenna.

Embodiments disclosed herein relate to an apparatus that includes a chamber with an interior surface and a radio frequency (RF) input coupled to the interior surface. In an embodiment, a sensor system is coupled to the interior surface of the chamber. In an embodiment, the sensor system includes a board, a sensor antenna on the board, and a sensor communicatively coupled to the sensor antenna.

Embodiments disclosed herein relate to an apparatus that includes a housing with an opening. In an embodiment, a board is within the housing, and a first sensor is on the board. In an embodiment, the first sensor is positioned at least partially within a footprint of the opening, and a second sensor is on the board, where the second sensor is entirely outside of the footprint of the opening. In an embodiment, an antenna is on the board, and the antenna is configured to wirelessly couple to an RF power source and provide power to the first sensor and the second sensor.

### BRIEF DESCRIPTION OF THE DRAWINGS

FIG. 1 is a perspective view illustration of a portion of a chamber that comprises an internal sensor system that is wirelessly coupled to a chamber antenna, in accordance with an embodiment.

FIG. 2 is a plan view illustration of a sensor system with sensors and an antenna provided on a board, in accordance with an embodiment.

FIG. 3A is a plan view illustration of an antenna within a chamber, in accordance with an embodiment.

FIG. 3B is a plan view illustration of a spiral antenna within a chamber, in accordance with an embodiment.

FIG. 4 is an exploded view of a sensor system, in accordance with an embodiment.

FIG. 5 is a cross-sectional illustration of a chamber with a sensor system that is wirelessly coupled to a chamber antenna for power delivery and data transmission, in accordance with an embodiment.

FIG. 6 is a perspective view illustration of a portion of a chamber with a chamber liner that is coupled to an RF input and wirelessly coupled to a sensor system, in accordance with an embodiment.

FIG. 7 is a cross-sectional illustration of a chamber with a sensor system that is wirelessly coupled to a chamber liner for power delivery and data transmission, in accordance with an embodiment.

FIG. 8 is a process flow diagram of a process for monitoring an interior chamber condition with a sensor system that is wirelessly powered through RF power delivery, in accordance with an embodiment.

FIG. 9 illustrates a block diagram of an exemplary computer system of a processing tool, in accordance with an embodiment of the present disclosure.

### DETAILED DESCRIPTION

Passive wireless chamber sensors that are powered through RF power delivered to the chamber are described herein in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, chamber monitoring is important in order to maintain high performance processing within the chamber. For example, deposition of layers on interior chamber surfaces can result in non-uniform processing and/or provide a source of defects that can deposit onto the substrate within the chamber. Some previous solutions include providing a coupon within the chamber. After one or more iterations of a processing operation within the chamber, the chamber is vented in order to remove the coupon. The coupon is then analyzed in order to track changes to the interior chamber surface. However, this requires frequent venting of the chamber, and takes the chamber offline for long durations. Additionally, coupons only allow for a snapshot of the end of the process.

Some active sensors have been proposed to monitor the chamber condition. However, the inclusion of such sensors require batteries or other energy storage in order to power the sensors. Since the sensors are battery powered, the duration of sensor use is limited. Ultimately, the chamber still needs to be vented in order to retrieve the sensor. Additionally, the sensors need to be designed to withstand the harsh environment of a plasma processing chamber. This can lead to relatively large sensors that may impact plasma processing to some extent.

Accordingly, embodiments disclosed herein include a passive sensor system. In some embodiments, the passive sensor system comprises a sensor antenna and one or more sensors. The sensor antenna can provide wireless power coupling (e.g., through radio frequency (RF) power delivery) in order to power the one or more sensors. The sensor antenna can also be used to provide wireless data transmission. This allows for real time (or near real time) analysis of changing chamber conditions. The chamber may include a chamber antenna that provides the wireless coupling to the sensor antenna. The chamber antenna may be an electrically conductive rod, spiral, or the like. In other embodiments, a portion of the chamber itself may be used as the chamber antenna. For example, a chamber liner may be coupled to an RF input in order to provide the wireless coupling to the sensor antenna.

The use of such a passive sensor system is advantageous for several reasons. In one embodiment, the lack of an on-board power storage device allows for the passive sensor to operate for any duration. For example, the passive sensor may operate the entire duration of chamber operation between planned maintenance (PM) events. As such, there is no additional downtime for the chamber to accommodate the sensor system. This increases uptime and improves throughput. Additionally, passive sensor systems can be designed with a small form factor since there is no need to include a battery, a memory, a processor, or the like. The small form factor may also allow for the inclusion of multiple sensor systems within the chamber, and/or the ability to mount the sensor system to many different surfaces within the chamber. For example, the sensor system may be provided on a chamber wall, a chamber liner, a process kit, a chamber lid, and/or the like. Omitting one or more of such additional components may also benefit the sensor system's ability to withstand harsh plasma environments. Another advantage of embodiments disclosed herein is that the passive sensor system allows for real time (or near real time) monitoring of changes within the chamber.

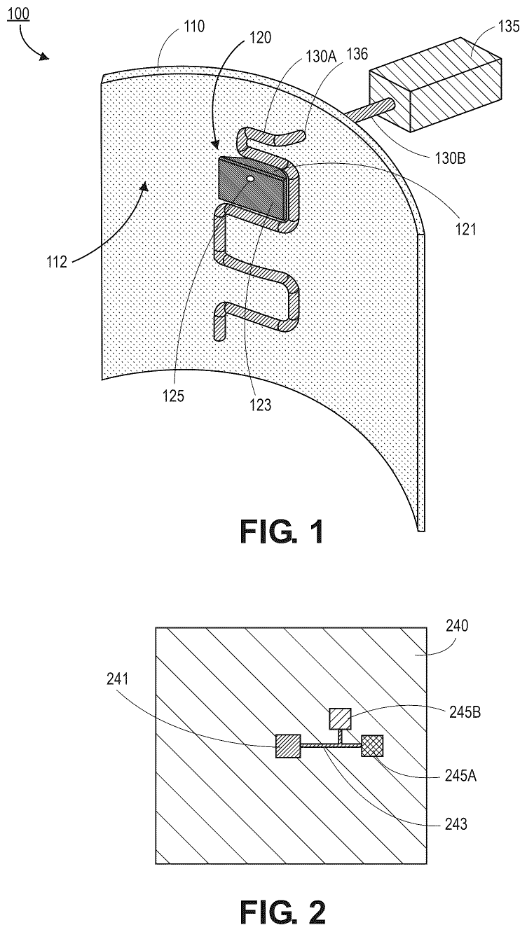

Referring now to FIG. 1, a perspective view illustration of a portion of a chamber 100 is shown, in accordance with an embodiment. In an embodiment, the chamber 100 may be a vacuum chamber suitable for plasma processing (e.g., plasma enhanced deposition processes, plasma etching process, plasma treatment processes, and/or the like). Though, it is to be appreciated that embodiments may also be used in chambers that do not include plasma generation. In FIG. 1, a portion of the chamber wall 110 is shown. The chamber wall 110 may have an interior surface 112 that is provided within the enclosed volume of the chamber 100. In an embodiment, the chamber wall 110 may comprise any suitable material, such as a metallic material or the like. The interior surface 112 may comprise bare metal, or the interior surface 112 may be coated. For example, a ceramic coating that is resistant to plasma chemistries within the chamber 100 may be provided over the interior surface 112. While illustrated with an open top and bottom, it is to be appreciated that the chamber wall 110 may provide a complete enclosure. A lid (not shown) may also form a portion of the complete enclosure of the chamber 100.

In an embodiment, a passive sensor system 120 may be provided within the chamber 100. That is, the passive sensor system 120 may be provided in the enclosed volume of the chamber 100. In the illustrated embodiment, the sensor system 120 may be provided on a wall of the interior surface 112. However, as will be described in greater detail herein, the sensor system 120 may be positioned at any location within the chamber 100.

In an embodiment, the sensor system 120 may comprise a housing 121. The housing 121 may be sealed by a lid 123. The components of the sensor system 120 (e.g., sensor antenna and one or more sensors) are not visible in FIG. 1, and will be described in greater detail herein. In an embodiment, a hole 125 or opening may be provided through the lid 123. The hole 125 allows for one or more sensors within the sensor system 120 to be exposed to the plasma environment within the interior volume of the chamber 100. The housing 121 and/or the lid 123 may comprise any suitable material capable of withstanding the environmental conditions within the chamber 100. In some embodiments, the housing 121 and/or the lid 123 may comprise a ceramic material or a metallic material that is lined with a ceramic. The lid 123 may be sealed against the housing 121 with any suitable mechanism. For example, a clamp, a latch, a magnet, a snap, or the like may be used to retain the lid 123 against the housing 121.

In an embodiment, the sensor system 120 is wirelessly coupled to a chamber antenna 130A within an interior of the chamber 100. The wireless coupling between the sensor system 120 and the chamber antenna 130A may provide wireless power delivery to the sensor system 120. Additionally, the wireless coupling between the sensor system 120 and the chamber antenna 130A may provide wireless data transfer between the sensor system 120 and an external device 135. The external device 135 may comprise circuitry for receiving and/or processing data from the sensor system 120. The external device 135 may comprise a processor, a memory, or the like. The external device 135 may be a computing device, a server, a controller, or any other suitable device for receiving and/or processing data. In some embodiments, the external device 135 may be referred to as a reader. The external device 135 may also comprise an RF power source or power supply in order to provide RF power that can be coupled into the chamber 100 in order to wirelessly power the sensor system 120.

In an embodiment, the chamber antenna 130A may pass through a port 136 in the chamber wall 110. The chamber antenna 130A may be electrically insulated from the chamber wall 110 through the port 136. An external portion 130B of the chamber antenna 130A may extend from an exterior of the chamber wall 110, and the external portion 130B may be electrically coupled to the external device 135. In an embodiment, RF frequencies suitable for wireless power delivery from the chamber antenna 130A to the sensor system 120 may range from 100 MHz to 100 GHz. Though, lower frequencies or higher frequencies for the RF power may also be used in some embodiments.

In an embodiment, the sensor system 120 may be mounted to interior surfaces of the chamber 100 with any suitable structure, attractive force, and/or the like. In the embodiment shown in FIG. 1, the sensor system 120 is retained by the chamber antenna 130A. For example, one of the bends in the chamber antenna 130A is sized to receive the sensor system 120. As such, the sensor system 120 can be inserted into the receiving bend of the chamber antenna 130A. The chamber antenna 130A may also comprise other retention mechanisms (not shown) in order to more securely hold the sensor system 120 in place. In an embodiment, the chamber antenna 130A may directly contact one or more surfaces of the housing 121 and/or lid 123 of the sensor system 120.

Referring now to FIG. 2, a plan view illustration of a board 240 that is provided as part of the sensor system 120 is shown, in accordance with an embodiment. The board 240 may comprise a printed circuit board (PCB) or other organic based board structure. The board 240 may also comprise inorganic based boards, such as a ceramic board, or the like. The board 240 may be sized to fit within the housing 121, and the lid 123 may cover at least a portion of the board 240.

In an embodiment, the board 240 may comprise a sensor antenna 241 and one or more sensors (e.g., sensor 245A and 245B). In the illustrated embodiment, the sensor antenna 241 comprises a conductive pad, such as an input pad. While a specific structure for the sensor antenna 241 is shown in FIG. 2, it is to be appreciated that the sensor antenna 241 may have any shape and/or design that allows for wireless coupling with the chamber antenna 130A. For example, the sensor antenna 241 may be a spiral antenna, a trace, or the like. More generally, the sensor antenna 241 may comprise a monopole antenna, a dipole antenna, a patch antenna, a planar inverted F-antenna, or the like.

In an embodiment, the sensor antenna 241 may be electrically coupled to the one or more sensors 245A and 245B. For example, one or more traces 243 on and/or embedded within the board 240 may provide an electrical connection between the sensor antenna 241 and the one or more sensors 245A and 245B. In the illustrated embodiment, the one or more sensors 245A and 245B may comprise any suitable impedance sensor. For example, the one or more sensors 245A and 245B may comprise a surface acoustic wave (SAW) sensor and/or a bulk acoustic wave (BAW) sensor. The sensors 245A and 245B may be printed directly onto the board 240, or the sensors 245A and 245B may be part of a discrete component mounted to the board 240.

In the case of a pair of sensors 245A and 245B, the pair can be used for differential sensing. For example, the first sensor 245A may be exposed to the plasma environment, and the second sensor 245B may be protected from the plasma environment. This allows for effects attributable to temperature and the like to be controlled for while allowing measurement of material deposition over the first sensor 245A. In an embodiment, the second sensor 245B may be protected by a portion of the housing 121 and/or lid 123. In other embodiments, a layer (e.g., an organic layer, such as a solder resist or the like) may be provided over the second sensor 245B.

In an embodiment, the one or more sensors 245A and 245B may be configured to determine the thickness of a material layer that is deposited on the first sensor 245A during operation of the chamber 100. The thickness of the layer deposited on the first sensor 245A can be correlated to the thickness of the material deposited on interior surfaces of the chamber 100 proximate to the location of the sensor system 120. In some embodiments, a sensitivity of the one or more sensors 245A and 245B may be 10 nm or lower, 5 nm or lower, or 2 nm or lower. Embodiments disclosed herein may also include sensors 245A and 245B that are configured to determine a material composition of the layer deposited on the first sensor 245A or a change in material composition of the layer deposited on the first sensor 245A.

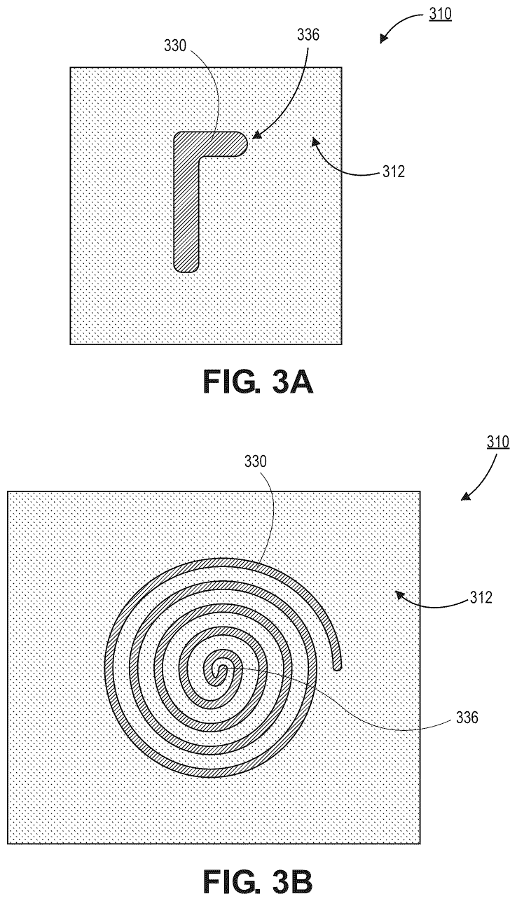

Referring now to FIGS. 3A and 3B, a pair of plan view illustrations of an interior surface 312 of a chamber wall 310 is shown, in accordance with different embodiments. The illustrations in FIG. 3A and FIG. 3B provide exemplary depictions of different chamber antennas 330 that may be used in some embodiments. In an embodiment, the chamber antenna 330 in FIG. 3A is a monopole antenna that enters the chamber wall 310 through a port 336. The chamber antenna 330 may have a lateral turn and then extend down in a vertical direction. Though, it is to be appreciated that the chamber antenna 330 may have any desired path along the interior surface 312 of the chamber wall 310. FIG. 3B is an additional configuration that shows a spiral chamber antenna 330. The chamber antenna 330 may pass through the chamber wall 310 at a port 336 towards a center of the spiral.

Additional embodiments may include a chamber antenna 330 that wraps around a perimeter of the interior surface 312 of the chamber wall 310. Further, while the chamber antenna 330 is shown as being against the interior surface 312 of the chamber wall 310, other embodiments may include a chamber antenna 330 that is proximate to a chamber lid, a chamber liner, a process kit, or any other surface within the chamber.

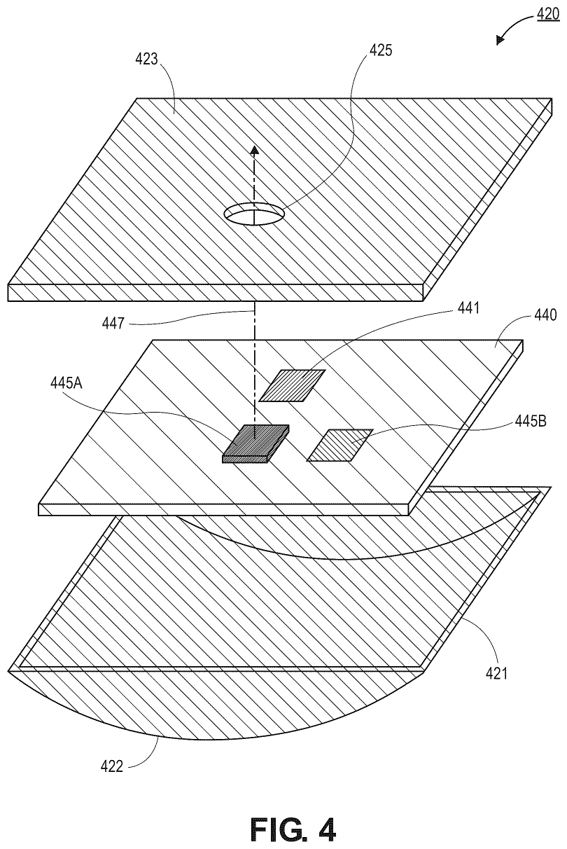

Referring now to FIG. 4, an exploded view of a sensor system 420 is shown, in accordance with an embodiment. In an embodiment, the sensor system 420 may comprise a housing 421. In an embodiment, the housing 421 may comprise a curved surface 422. The curvature of the curved surface 422 may match a curvature of an interior surface of the chamber wall. As such, the housing 421 may sit flush against the interior surface of the chamber wall. The housing 421 may comprise any suitable material or materials, similar to any of those described above with respect to the housing 121 described in greater detail herein.

In an embodiment, a board 440 may be provided in the sensor system 420. That is, the housing 421 may be provided around the board 440. For example, the housing 421 may cover at least a backside surface of the board 440 and sidewalls of the board 440. The board 440 may be sized to fit into the housing 421. The board 440 may be retained within the housing 421 with any suitable mechanical features (not shown), such as clips, latches, notches, snaps, and/or the like. The board 440 may also be secured against the housing 421 by the lid 423 in some embodiments. The board 440 may comprise an antenna 441. In the embodiment shown in FIG. 4, the antenna 441 comprises a pad, such as an input pad for the antenna 441. Though, it is to be appreciated that any antenna structure may be used for the antenna 441 in other embodiments. For example, the antenna 441 may be similar to any of the embodiments described with respect to the sensor antenna 241 in FIG. 2.

In an embodiment, the antenna 441 may be electrically coupled to one or more sensors 445A and 445B. For example, electrical traces (not shown) below the surface of the board 440 may electrically connect the antenna 441 to the one or more sensors 445A and 445B. The sensors 445A and 445B may be impedance sensors, such as a BAW sensor and/or a SAW sensor. The sensors 445A and 445B may be similar to any of the embodiments described above with respect to sensors 245A and 245B. In an embodiment, the first sensor 445A may be exposed, and the second sensor 445B may be covered by a layer (as indicated by the different shading). Accordingly, differential sensing solutions can be used to control for various chamber conditions.

In an embodiment, the sensor system 420 may also comprise a lid 423. The lid 423 may substantially seal the housing 421. For example, the lid 423 may be mechanically coupled to the housing 421 by a latch, a clip, a snap, a magnet, and/or the like. In an embodiment, a hole 425 is provided through the lid 423. The hole 425 may be aligned over the first sensor 445A in order to expose the first sensor 445A to the plasma environment of the chamber. For example, the footprint of the first sensor 445A may be at least partially within a footprint of the hole 425. In the embodiment shown in FIG. 4, a centerline of the first sensor 445A is aligned with a centerline of the hole 425 along line 447. The housing 421 and the lid 423 may be coupled together to provide an enclosure around the board 440, the antenna 441, and the sensors 445A and 445B in some embodiments.

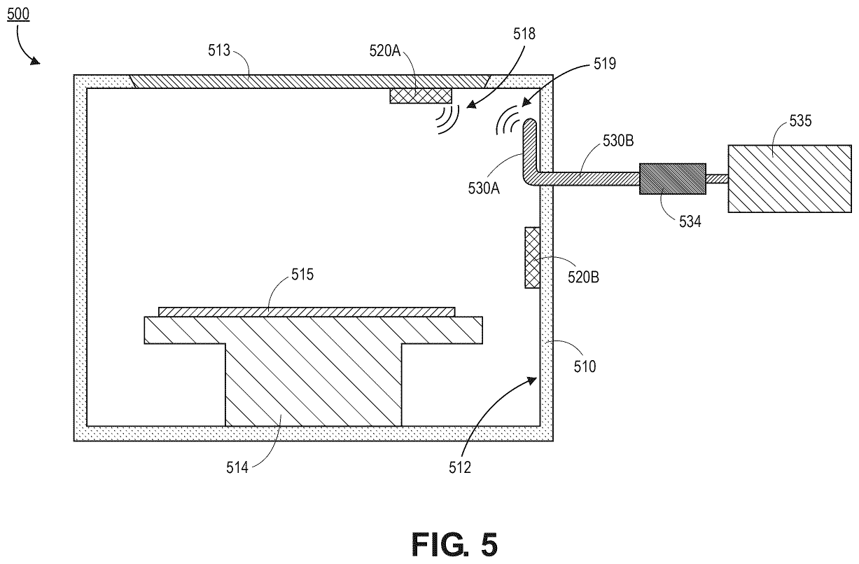

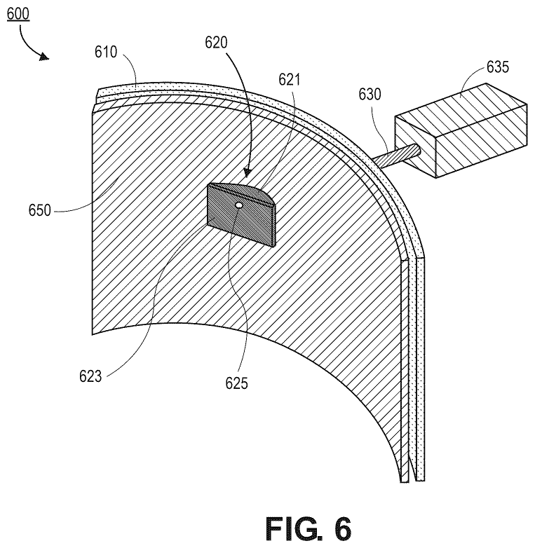

Referring now to FIG. 5, a cross-sectional illustration of a chamber 500 is shown, in accordance with an embodiment. In an embodiment, the chamber 500 comprises a chamber wall 510. The chamber wall 510 may be sealed by a lid 513. The lid 513 may include gas distribution features (not shown), and the lid 513 may be coupled to an RF or microwave power source to ignite and sustain a plasma within the chamber 500. In an embodiment, a pedestal 514 within the chamber 500 is configured to support a substrate 515. The pedestal 514 may include a chucking feature (e.g., an electrostatic chuck (ESC)) to retain the substrate 515 on the pedestal 514. The substrate 515 may be a semiconductor substrate (e.g., a silicon wafer), an organic substrate (e.g., a panel for electronic packaging fabrication), a glass panel, and/or the like.

In an embodiment, one or more sensor systems 520 may be provided along interior surfaces of the chamber 500. For example, a first sensor system 520A may be provided on the chamber lid 513, and a second sensor system 520B may be provided on an interior surface 512 of the chamber wall 510. In an embodiment, a chamber antenna 530A may pass through the chamber wall 510. The chamber antenna 530A may be wirelessly coupled to the one or more sensor systems 520. For example, RF power 519 may be propagated from the chamber antenna 530 to one or more of the sensor systems 520. Additionally, data 518 relating to a chamber condition detected by the one or more sensor systems 520 may be propagated from the sensor systems 520 to the chamber antenna 530A. That is, RF power is delivered to the sensor systems 520, the RF power is used to power sensors within the sensor systems 520, the sensors detect the chamber condition, and the sensor system 520 delivers data related to the chamber condition back to the chamber antenna 530A. In an embodiment, the one or more sensor systems 520 may be similar to any of the sensor systems described in greater detail herein. That is, the sensor systems 520 may be passive and comprise a sensor antenna and one or more impedance sensors in some embodiments.

In an embodiment, the chamber antenna 530A is coupled to an external device 535 through an external portion 530B of the chamber antenna 530A. In a particular embodiment, a filter and/or match component 534 may be provided between the external portion 530B of the chamber antenna 530A and the external device 535. The external device 535 may be similar to the external device 135 described in greater detail herein.

Referring now to FIG. 6, a perspective view illustration of a portion of a chamber 600 is shown, in accordance with an additional embodiment. In an embodiment, the chamber 600 may be a vacuum chamber suitable for plasma processing (e.g., plasma enhanced deposition processes, plasma etching process, plasma treatment processes, and/or the like). Though, it is to be appreciated that embodiments may also be used in chambers that do not include plasma generation. In FIG. 6, a portion of the chamber wall 610 is shown. In an embodiment, the chamber wall 610 may comprise any suitable material, such as a metallic material or the like. The interior surface may comprise bare metal, or the interior surface may be coated. For example, a ceramic coating that is resistant to plasma chemistries within the chamber 600 may be provided over the interior surface. While illustrated with an open top and bottom, it is to be appreciated that the chamber wall 610 may provide a complete enclosure. A lid (not shown) may also form a portion of the complete enclosure of the chamber 600.

In an embodiment, a chamber liner 650 may be provided inside the chamber wall 610. The chamber liner 650 may comprise an electrically conductive material. The chamber liner 650 may be coated with a ceramic or the like. The chamber liner 650 is shown as being the same height as the chamber wall 610. Though, in other embodiments, the chamber liner 650 may be shorter than the chamber wall 610.

In an embodiment, a passive sensor system 620 may be provided within the chamber 600. That is, the passive sensor system 620 may be provided in the enclosed volume of the chamber 600. In the illustrated embodiment, the sensor system 620 may be provided on a wall of the chamber liner 650. However, as will be described in greater detail herein, the sensor system 620 may be positioned at any location within the chamber 600.

In an embodiment, the sensor system 620 may be similar to any of the sensor systems described in greater detail herein. For example, the sensor system 620 may comprise a housing 621 and a lid 623 with a hole 625. In an embodiment, the sensor system 620 may be a passive device and comprise a sensor antenna and one or more impedance sensors (not visible in FIG. 6).

In an embodiment, the sensor system 620 is wirelessly coupled to the chamber liner 650. The wireless coupling between the sensor system 620 and the chamber liner 650 may provide wireless power delivery to the sensor system 620. Additionally, the wireless coupling between the sensor system 620 and the chamber liner 650 may provide wireless data transfer between the sensor system 620 and an external device 635. The external device 635 may be similar to any of the external devices described in greater detail herein.

In an embodiment, the chamber liner 650 may be electrically coupled to an RF input 630 from the external device 635. The RF input 630 may pass through a port (not visible) in the chamber wall 610. The RF input 630 may be electrically insulated from the chamber wall 610 through the port. In an embodiment, RF frequencies suitable for wireless power delivery from the chamber liner 650 to the sensor system 620 may range from 100 MHz to 100 GHz. Though, lower frequencies or higher frequencies for the RF power may also be used in some embodiments. While the RF input is shown as being coupled to the chamber liner 650, it is to be appreciated that the RF input may be coupled to any component within the chamber 600 that can function as an antenna structure. For example, the RF input may be coupled to a process kit, a lid, and/or a chamber wall.

In an embodiment, the sensor system 620 may be mounted to the chamber liner 650 with any suitable structure, attractive force, and/or the like. In the embodiment shown in FIG. 6, the sensor system 620 is floating. Though, it is to be appreciated that a ledge or slot in the chamber liner 650 may be used in order to retain the sensor system 620.

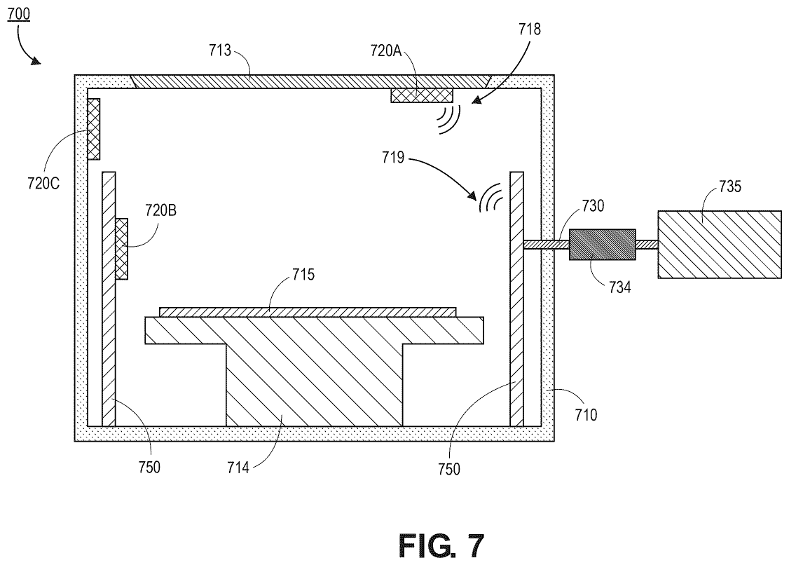

Referring now to FIG. 7, a cross-sectional illustration of a chamber 700 is shown, in accordance with an embodiment. In an embodiment, the chamber 700 comprises a chamber wall 710. The chamber wall 710 may be sealed by a lid 713. The lid 713 may include gas distribution features (not shown), and the lid 713 may be coupled to an RF or microwave power source to ignite and sustain a plasma within the chamber 700. In an embodiment, a pedestal 714 within the chamber 700 is configured to support a substrate 715. The pedestal 714 may include a chucking feature (e.g., an ESC) to retain the substrate 715 on the pedestal 714. The substrate 715 may be similar to any of the substrates described in greater detail herein.

In an embodiment, one or more sensor systems 720 may be provided along interior surfaces of the chamber 700. For example, a first sensor system 720A may be provided on the chamber lid 713, and a second sensor system 720B may be provided on an interior surface of a chamber liner 750. In an embodiment, a third sensor system 720C may be on an interior surface of the chamber wall 710. In an embodiment, an RF input 730 may pass through the chamber wall 710 and electrically connect to the chamber liner 750. The chamber liner 750 may be wirelessly coupled to the one or more sensor systems 720. For example, RF power 719 may be propagated from the chamber liner 750 to one or more of the sensor systems 720. Additionally, data 718 relating to a chamber condition detected by the one or more sensor systems 720 may be propagated from the sensor systems 720 to the chamber liner 750. That is, RF power is delivered to the sensor systems 720, the RF power is used to power sensors within the sensor systems 720, the sensors detect the chamber condition, and the sensor system 720 delivers data related to the chamber condition back to the chamber liner 750. In an embodiment, the one or more sensor systems 720 may be similar to any of the sensor systems described in greater detail herein. That is, the sensor systems 720 may be passive and comprise a sensor antenna and one or more impedance sensors in some embodiments.

In an embodiment, the chamber liner 750 is coupled to an external device 735 by the RF input 730 with a filter and/or match component 734 provided between the RF input 730 and the external device 735. The external device 735 may be similar to the external device 135 described in greater detail herein.

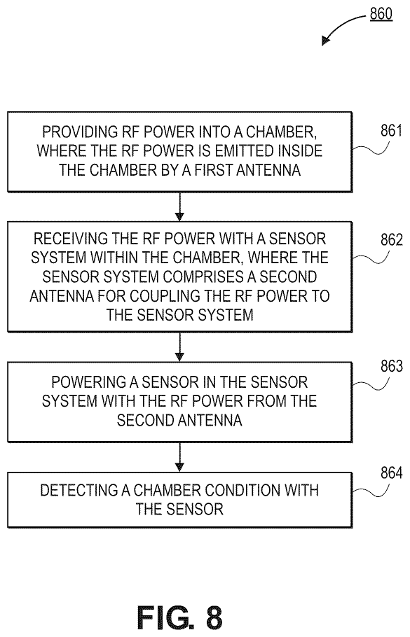

Referring now to FIG. 8, a process flow diagram of a process 860 for sensing a chamber condition with a wireless and passive sensor system is shown, in accordance with an embodiment. In an embodiment, the process 860 may begin with operation 861, which comprises providing RF power into a chamber. In an embodiment, the RF power is emitted inside the chamber by a first antenna. The first antenna may be a discrete antenna structure, or the first antenna may be a chamber liner, a lid, a process kit, or the like.

In an embodiment, the process 860 may continue with operation 862, which comprises receiving the RF power with a sensor system within the chamber. In an embodiment, the sensor system comprises a second antenna for coupling the RF power to the sensor system. More generally, the sensor system may be similar to any of the sensor systems described in greater detail herein. For example, the sensor system may comprise a passive sensor system that does not include a battery or other power storage device. In an embodiment, the process 860 may continue with operation 863, which comprises powering a sensor in the sensor system with the RF power from the second antenna. In an embodiment, the process 860 may continue with operation 864, which comprises detecting a chamber condition with the sensor. In an embodiment, the sensor may be an impedance sensor (e.g., a BAW sensor and/or a SAW sensor). Multiple sensors may be used in the sensor system to provide differential sensor monitoring in some embodiments. In an embodiment, the chamber condition may include a thickness of a material deposited on one or more surfaces of the chamber, a material composition of the layer deposited on one or more surfaces of the chamber, or a change in material composition of the layer deposited on one or more surfaces of the chamber.

In an embodiment, the process 860 may continue with delivering data corresponding to the chamber condition from the sensor system back to the first antenna. For example, the data may be delivered wirelessly by the second antenna to the first antenna. The first antenna may be communicatively coupled to an external device (e.g., a reader) that is capable of collecting, storing, and/or analyzing the data in order to monitor the chamber condition.

In some embodiments, the process 860 may be used in combination with machine learning (ML) and/or artificial intelligence (AI) systems in order to provide enhanced control of the chamber monitoring. For example, chamber condition data obtained from the sensor system can be fed into an ML and/or AI module in order to inform PM schedules. The data can be used by itself or in combination with historical sensor system data and/or other data sources related to the chamber, the substrates processed in the chamber, workflow through a fabrication (FAB) environment, and/or the like in order to schedule PM events. This can be used to maximize one or more of processing uniformity, throughput, chamber utilization, chamber matching, and/or the like. The combination of chamber condition data from the sensor system and metrology data from processed substrates can also be fed into one or more ML and/or AI systems in order to optimize substrate processing uniformity, accuracy, and/or the like.

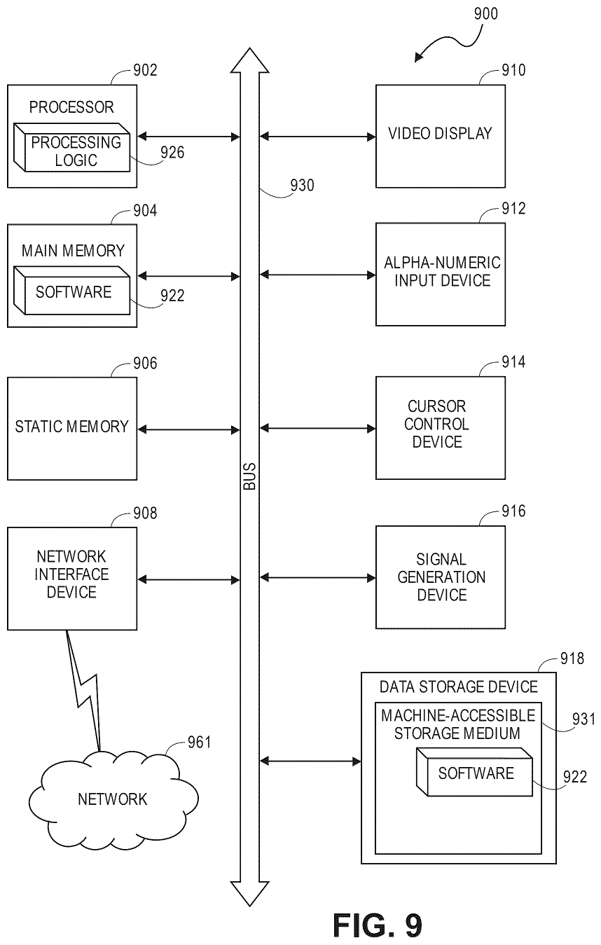

Referring now to FIG. 9, a block diagram of an exemplary computer system 900 of a processing tool is illustrated in accordance with an embodiment. In an embodiment, computer system 900 is coupled to and controls processing in the processing tool. The computer system 900 may be communicatively coupled to one or more vapor concentration sensor modules, such as those disclosed herein. The computer system 900 may utilize outputs from the one or more vapor concentration sensor modules in order to modify one or more parameters, such as, for example, processing recipe parameters, cleaning schedules for the processing tool, component replacement determinations, and the like.

Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using RF coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include passive sensors with wireless power and data coupling in order to monitor chamber conditions.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a chamber with an interior surface;
a sensor system coupled to the interior surface, wherein the sensor system comprises:
a board;
a sensor antenna on the board; and
a sensor communicatively coupled to the sensor antenna, wherein the sensor is configured to be powered by the sensor antenna; and
a chamber antenna within the chamber, wherein the chamber antenna is configured to communicatively couple with the sensor antenna.

2. The apparatus of claim 1, wherein the sensor system further comprises:
a housing around the board, the sensor antenna, and the sensor, and wherein the housing comprises an opening.

3. The apparatus of claim 1, wherein the sensor comprises:
a first sensor exposed to an interior environment of the chamber; and
a second sensor that is protected from the interior environment of the chamber.

4. The apparatus of claim 1, wherein the interior surface is a chamber wall, a chamber liner, a lid, or a process kit.

5. The apparatus of claim 1, wherein the chamber antenna is configured to provide power to the sensor system through wireless coupling with the sensor antenna.

6. The apparatus of claim 1, wherein the chamber antenna and the sensor antenna are communicatively coupled to provide data transfer between the sensor system and the chamber antenna.

7. The apparatus of claim 1, further comprising:
a match and a filter connected to the chamber antenna.

8. The apparatus of claim 1, wherein the sensor system is retained within the chamber by the chamber antenna.

9. The apparatus of claim 1, wherein the sensor comprises an impedance sensor including one or both of a surface acoustic wave (SAW) sensor or a bulk acoustic wave (BAW) sensor.

10. The apparatus of claim 1, wherein the sensor system is configured to measure a thickness of a layer deposited on the interior surface, a material composition of the layer deposited on the interior surface, or a change in the material composition of the layer deposited on the interior surface.

11. An apparatus, comprising:
a chamber with an interior surface;
a radio frequency (RF) input coupled to the interior surface; and
a sensor system coupled to the interior surface of the chamber, wherein the sensor system comprises:
a board;
a sensor antenna on the board; and
a sensor communicatively coupled to the sensor antenna.

12. The apparatus of claim 11, wherein the interior surface comprises a chamber wall, chamber lid, or a chamber liner.

13. The apparatus of claim 11, wherein the sensor antenna is wirelessly coupled to the interior surface so that the interior surface is configured to provide RF power to the sensor system.

14. The apparatus of claim 13, wherein the sensor antenna is wirelessly coupled to the interior surface so that data can be transferred out of the chamber through the RF input.

15. The apparatus of claim 11, further comprising:
a match and a filter between the interior surface and the RF input; and
a reader, wherein the reader is configured to collect and/or analyze an RF signal obtained from the sensor system.

16. The apparatus of claim 11, wherein the sensor system further comprises:
a housing around the board, the sensor antenna, and the sensor, and wherein the housing comprises an opening.

17. The apparatus of claim 11, wherein the sensor system is configured to measure a thickness of a layer deposited on the interior surface, a material composition of the layer deposited on the interior surface, or a change in the material composition of the layer deposited on the interior surface.

18. An apparatus, comprising:
a housing with an opening;
a board within the housing;
a first sensor on the board, wherein the first sensor is positioned at least partially within a footprint of the opening;
a second sensor on the board, wherein the second sensor is entirely outside of the footprint of the opening; and
an antenna on the board, wherein the antenna is configured to wirelessly couple to an RF power source and provide power to the first sensor and the second sensor.

19. The apparatus of claim 18, wherein the first sensor and the second sensor are impedance sensors.

20. The apparatus of claim 19, wherein the impedance sensors are surface acoustic wave (SAW) sensors or a bulk acoustic wave (BAW) sensors, and wherein the impedance sensors are configured to measure a thickness of a layer deposited on one or both of the impedance sensors, a material composition of the layer deposited on one or both of the impedance sensors, or a change in the material composition of the layer deposited on one or both of the impedance sensors.
